(19) United States
(12) Patent Application Publication
(10) Pub. No.: US 2012/0251427 A1
(43) Pub. Date: Oct. 4, 2012

(54) REACTOR AND METHOD FOR PRODUCTION OF SILICON

(76) Inventors: Josef Filtvedt, Tomter (NO); Werner O. Filtvedt, Tomter (NO); Arve Holt, Leirsund (NO)

(21) Appl. No.: 13/508,604

(22) PCT Filed: Nov. 25, 2010
(86) PCT No.: PCT/NO10/00431

§ 371 Date: Jun. 14, 2012

(51) Int. Cl. B01J 19/00; C23C 16/24; B01J 19/28

(52) U.S. Cl. 423/349; 422/129; 422/240; 422/198; 422/209

(57) ABSTRACT

Reactor for production of silicon, comprising a reactor volume, distinctive in that the reactor comprises or is operatively arranged to at least one means for setting a silicon-containing reaction gas for chemical vapor deposition (CVD) into rotation inside the reactor volume. Method for production of silicon.

### FIELD OF THE INVENTION

The present invention relates to production of silicon for use in solar cells and electronics. More specifically, the invention relates to a reactor and a method for production of silicon and use of the reactor.

### BACKGROUND OF THE INVENTION AND PRIOR ART

The development of new techniques to utilize renewable, non-polluting sources of energy is essential in order to meet the future energy requirements. In this context, solar energy is among the most interesting energy sources.

Silicon is a critical raw material in both the electronic industry as well as the solar cell industry. Although there are alternative materials for special applications, polycrystalline and monocrystalline silicon will remain the preferred materials in the foreseeable future. Improved availability and economy when producing polycrystalline silicon will increase the opportunity of growth in both industries as well as increase the use of solar cells as renewable energy.

In order to produce silicon of sufficient purity for use in solar cells or electronics, methods for chemical vapor deposition are now commonly used. Different versions of the Siemens process are the most widespread methods for CVD used to produce polycrystalline silicon. A silicon-containing gas, such as silane or trichlorosilane, or another gas, such as hydrogen gas or argon, is fed into a vessel and silicon deposits onto a resistance heated rod. The power and labor requirements are high. A more detailed description of the process is given in the patent publication U.S. Pat. No. 3,979,490. One of the problems with today's CVD reactors and particularly the Siemens reactor is that they utilize only parts of the reaction gas which is fed into the reactor. Much of the gas passes straight through the reactor and escapes from the reactor as part of the residual gas. This occurs due to the fact that it is only gas diffusion that drives the reaction gas inside the reactor. This results in a slow gas flow and much of the reaction gas never reaches the reaction surface before it escapes from the reactor. In order to avoid wasting the unused silicon-containing gas, the exhaust from the CVD reactor needs to go through a comprehensive and costly cleaning process.

Another less commonly used method for CVD is fluidized bed, wherein silicon seed particles are surrounded by and kept in an ascending gas flow, as the gas flow comprises silicon-containing gas, from which silicon can deposit onto the seed particles. The advantage of using this fluidized bed is the vast surface area onto which silicon can deposit, which enables the possibility of increased and continuous production as well as lower energy consumption. However, a practical and simple way to bring out particles that has grown sufficiently large is hard to achieve in practice. More precisely, it is hard to control the particle size in a fluidized bed reactor, and it is very hard to control the distribution of the particles in the operating reactor. The uneven distribution of the particles affects the flow state, which again affects the temperature distribution and the deposition of silicon. The method requires adding new particles from outside, or small particles forming in the reactor during operation. The drainage of large particles in the bottom of the reactor, as well as the addition of small particles that should increase in size, requires at the same time controlling many parameters, which has proven to be very hard in practical operation over time. A common problem in fluidized bed reactors is that particles grow together and gradually block the fluidization as well as unwanted deposition of silicon onto the inner surfaces of the reactor and nozzles, which causes the nozzles and the reactor volume to clog, thus stopping the production. The problem is discussed in the patent publication U.S. Pat. No. 4,818,495, column 2, line 40, to column 3, line 20, and in the patent publication U.S. Pat. No. 5,810,934. These patents also contain a thorough description of methods for CVD with a fluidizing bed and appurtenant equipment as well as operation parameters for the production of silicon, including gas mixtures, temperatures for deposits and problems and limitations.

A common problem with today's CVD reactors is that small silicon dust particles, so-called fines, are forming inside the reactor. This occurs if the gas reaches the decomposition temperature before it is close to a reaction surface, which can occur when small gas vortices form. These small silicon particles do not deposit onto the reaction surfaces and escapes from the reactor with the residual gas. Over time, fines constitute a considerable amount of silicon which is utilized only to a certain extent.

There is a need for an alternative technology which is advantageous with regard to one or more of the problems mentioned above.

The need is partially met by an invention, for which Dynatec Engineering applied for a patent on May 29, 2009, patent application NO 2009 2111. Said invention provides a reactor for producing silicon by chemical vapor deposition, comprising a reactor body which forms a vessel, at least one inlet for silicon-containing gas, at least one outlet and at least one heating device as a part of or operatively arranged to the reactor, distinctive in that at least one main part of the reactor body, which part is exposed to chemical vapor and heated for deposition of silicon onto said part, is produced from, i.e. made of, silicon.

The aforementioned fundamental idea of the reactor is that all of, or a substantial part of the material exposed to silicon-containing gas is made of silicon, advantageously of high purity, or another non-contaminating material, in such a way that deposition of silicon deliberately can be controlled to occur onto said materials. Known problems concerning the separation of silicon from other materials, as well as numerous of the problems concerning clogging are avoided or reduced. At the same time, there are many additional possibilities for how the reactor can be built and operated, including how the heating can be achieved. However, there is no description nor instructions as to any particular orientation of the inlet to the reactor in NO 2009 2111, nor as to any particular flow patterns except of fluidized bed, and the objective of the present invention is to further improve the reactor and the method for production of silicon.

### SUMMARY OF THE INVENTION

The objective is met by the invention providing a reactor for production of silicon, comprising a reactor volume, distinctive in that the reactor comprises or is operatively arranged to at least one means for setting a silicon-containing reaction gas for chemical vapor deposition (CVD) into rotation inside the reactor volume.

The means for setting a silicon-containing reaction gas for chemical vapor deposition (CVD) into rotation in the reactor volume is preferably a motor rotating the reactor. Additionally or alternatively, special inlet arrangements, such as several inlets on an end plate rotating with the reactor, angled inlets and spinning elements, can be employed. The reactor is preferably, with the inner surface, rotationally symmetric about a main axis, such as a vertical or horizontal tube with circular cross-section, in order to achieve an even flow pattern. The reactor can be one out of two main embodiments, namely a still-standing, non-rotating reactor and a rotary reactor. In the non-rotating reactor, the gas is put into rotation by angled inlets, vanes and/or spinning elements, in such a way that the gas obtains a tangential velocity component and achieves a helical path inside the reactor volume. In the rotary reactor a motor or equivalent is used for rotating the reactor, whereas the inlet can be stationary, or it can rotate with the reactor, and the inlet can possibly be arranged angularly or with a spinning element.

The most preferred embodiment is generally a rotary reactor without seed particles or fluidized bed, however, comprising an inlet rotating with the reactor, wherein more parallel streamlines thereby can be achieved, which yields a particularly advantageous result as this minimizes the formation of silicon dust particles (fines). The rotation causes a flow pattern which results in a very high concentration of silicon-containing reaction gas against the reactor wall, or more precisely the sidewall of said reactor, and the deposition of silicon can deliberately be controlled to occur onto the reactor wall in such a way that the reactor to a less or greater extent grows tight from deposited silicon. The most silicon-containing reaction gas will, after some time with rotation of the reactor, thereby be heavily concentrated towards the inner wall of the reactor, and said gas and wall will rotate at the same velocity, in such a way that turbulence which interferes with the flow and the separation effect of the gas and thus the deposition of silicon, is minimized. More parallel streamlines or flow pattern has surprisingly proved to be far more advantageous than other flow patterns.

A reaction gas typically comprises a silicon-containing gas, advantageously silane mixed with hydrogen gas. Hydrogen gas also constitutes the residual product after decomposition of silane and liberation of silicon. The reaction gas may also, in certain cases, contain small silicon particles, so-called fines. The basis of the invention lies in the great difference between the mass of silicon-containing gas and hydrogen gas, typically, silane weighs approximately 16 times more than hydrogen gas. According to Newton's second law, which says that force equals mass times acceleration, the heavy silicon-containing molecules will be exposed to a larger force than the light hydrogen molecules when the reaction gas is set into rotation. The rotation causes centripetal acceleration or centrifugal effect which results in a very effective separation effect and the heavy silicon-containing gas is pushed outwardly towards the reactor wall, onto which the deposition occurs. The reactor is adapted to controlled filling of deposited silicon, and therefore, at least one main part of the reactor is produced from, i.e. made of silicon or comprises an inner coating of silicon, such as circular cylindrical sidewalls of metallurgical or CVD silicon, or an EFG silicon tube or similar. More precisely, the reactor is operatively arranged to at least one heating device, which deliberately heats at least one part of or the whole reactor wall, in order to deliberately deposit silicon by CVD onto the wall, thereby completely filling the reactor volume with deposited silicon. In this way the whole reactor or the sidewall thereof, completely filled with deposited silicon, can be utilized as solar cell- or electronic silicon. However, reactors with other wall material than silicon and which walls are deliberately heated, completely or partly, are also applicable and are embodiments of the invention, inasmuch as the technical effect of the invention still is surprisingly good, particularly for a rotary reactor. The reactor tube can be produced from/made of other materials than silicon, for example reasonably priced silica quartz tubes which can be removed in their entirety after the reactor process. Deposited silicon can be melted out of a reactor without silicon walls or with only a EFG silicon coating, by induction melting or by another heating device such as a suitable furnace, optionally, contaminated wall elements can be machined or cut away.

The reactor is advantageously formed as a cylinder, arranged vertical or horizontal, with a circular inner cross-section, a motor for rotating the reactor is preferably operatively arranged to the reactor, an outlet for silicon-poor gas is coaxially arranged to the cylinder axis in at least one end, at least one heating device is operatively arranged on the outside or on the inside of the reactor, with or without inert gas and/or cooling gas protection. The reactor advantageously comprises at least one end plate rotating with the reactor, which end plate is equipped with one or more inlets for silicon-containing reaction gas. One or more inlets are arranged on and/or in different distance from the rotation axis, and the end plate can, for example, be sealingly and rotatably arranged to a supply chamber for reaction gas, as an example the end plate is a rotatable top on such chamber. Alternatively the supply chamber can rotate with the reactor, which makes the end plate a partition wall with nozzles between the supply chamber and the reactor volume. The outlet can preferably be arranged correspondingly. The end plates are preferably made of a material having lower thermal conductivity than the rest of the reactor, such as or alternatively a composite design comprising materials of different thermal conductivity in order to better maintain a reaction temperature of the reactor wall.

In an alternate embodiment the reactor is formed as a vertical standing cylinder with a circular or in substance circular cross-section, the sidewalls are produced of silicon of high-grade metallurgical quality or purer, and one or more inlets is or are angularly arranged in a bottom, in such a way that silicon-containing gas injected into the reactor follows a helical path upwardly along the wall towards an outlet in the top of the reactor, wherein the orientation of the inlet and the gas contain a direction component parallel to the cylinder axis and a direction component parallel to the circumference of the inner cylindrical wall. The reactor advantageously comprises, or is operatively positioned with regard to, a heating device on the outside of the reactor. The heating device is advantageously shaped as a helix parallel to a helical path followed by injected gas inside the reactor.

The invention also provides a method for production of silicon by vapor deposition and/or cleaning of a silicon containing gas, in a reactor according to the invention, distinctive by setting a silicon-containing reaction gas for chemical vapor deposition (CVD) into rotation inside the reactor volume, by operating at least one means for achieving such rotation, preferably using one or more reactors in parallel and/or series. This means that whilst silicon is deposited by operating the reactor at typical CVD operating parameters, at least a part of, preferably all of, the silicon-containing reaction gas is set into rotation, preferably by means or arrangements at an inlet for reaction gas and/or with a motor rotating the reactor. The operation of the reactor is a batch process or first a continuous process and later as a batch process.

Silicon is preferably deliberately deposited onto the reactor wall by chemical vapor deposition in such a way that the cross-section of the reactor in substance grows tight, whereupon the contents of the reactor or the contents of the reactor and the reactor wall can be utilized in further stages in a process for production of silicon for solar cell and/or electronic purposes. Most advantageously the reactor is rotated by a motor, due to the aforementioned causes, possibly the injection flow is directed in such a way that the silicon-containing gas follows a helical path along the inner wall of the reactor, preferably along the total length or height of the reactor.

The present invention also provides use of a reactor according to the invention, for producing silicon and/or cleaning a silicon containing reaction gas supplied from other reactors according to the invention or other types of CVD reactors, or the gas is originating from other sources.

The present invention builds further on the invention according to NO 2009 2111, with a reactor in which all of or a substantial part of the material exposed to silicon-containing gas is produced from/made of a non-contaminating material, preferably high-grade silicon, in such a way that deposition of silicon deliberately can be controlled to occur onto said materials. The present invention is distinct in that the silicon-containing reaction gas is set into rotation around the center line of the reactor, by rotating the whole or parts of the reactor, and/or by feeding said gas into the reactor through an upward slanting hole in the bottom plate or by using a spin element. When employing upward slanting holes, the reaction gas is fed into the reactor in such a way that said gas obtains a path along the reactor wall, preferably a helical path. Thus, the gas obtains a velocity component tangential to the reactor wall, in such a way that it rotates along the wall inside the reactor. At the same time, a vertical velocity component will force the reaction gas upwardly along the wall.

When employing upwardly inclined holes, the reactor will, in its simplest form, constitute a closed vessel with cylindrical or polygonal shape, in substance produced from/made of silicon or another non-contaminating material, which is utilized for chemical vapor deposition on the inside without silicon seed particles or fluidized bed. The gas flow is injected with a sloping angle with respect to the horizontal line, in such a way that it acquires a velocity component tangential to the wall and an upward velocity component in the reactor. The gas flow is fed into the reactor in such a way that it flows along the wall of the reactor and achieves rotation about the center line of the reactor. The reactor can be stationed in a heating chamber, however, in addition to/or in lieu of being in a heating chamber, a heating device can be operatively arranged in, on or outside the reactor. In order for the reaction gas to maintain the rotation, the reactor is preferably heated by heating elements which follows a helical path outside, around the reactor. Thusly, the heat can be controlled in such a manner that the depositions on the inside occur in such a way that the silicon initially is being deposited onto those parts of the wall closest to the heating elements. Consequently, the depositions will form a helical path which will aid the gas in maintaining its upward rotation in the reactor. The depositions will continue along the whole wall, whose area gradually will increase due to the helical shaped surface of the wall. The depositions occur until the wall has grown so tight that it is not possible or economically justifiable to continue the process. The advantage of feeding the gas flow in a helical path along the wall is that it will travel a longer distance compared with gas flowing directly upwards. This is advantageous in that the gas will be in contact with a larger area onto which deposition can occur, and it will spend more time from the bottom to the top of the reactor. This results in the possibility of depositing/liberating more of the silicon in the gas, thereby improving the gas utilization.

An alternative to arranging the inlet as aforementioned is to arrange a spinning element in the inlet, such as a spinning element in a central inlet. Arranging the inlet in such a way is a preferred embodiment in that changing different inlets can be performed without much effort. Spinning or spin elements can be implemented in many different ways, with static tracks and/or rotors, and are considered well known in the art, and will not be further described herein.

The big advantage of letting the gas rotate is assumed to be the occurrence of a centripetal force which will separate the reaction gas. In order for depositions to occur, there must be sufficient silicon-containing reaction gas near the heated silicon wall.

After the depositions have occurred, the remaining gas, poor in silicon (also termed silicon-poor residual gas), is the gas closest to the silicon wall. In order for further depositions to occur, new silicon-containing gas needs to pass the silicon-poor gas in order to get in contact with the wall. Silicon-containing gas, also termed silicon rich reaction gas, is heavier than the silicon-poor residual gas, which remains after liberating and depositing the silicon. As an example, silane gas is substantially heavier than hydrogen gas, which constitutes the residual gas after liberating the silicon. Since the gas moves upwardly in the reactor, the concentration of silicon in the gas will decrease, due to the depositing of silicon onto the wall. Gas with a high content of silicon will, due to its weight, achieve the highest centripetal acceleration. Thus, a concentration gradient in the gas will originate, with the highest silicon concentration along the reactor wall and the lowest silicon concentration towards the center. Thereby, the gas causing depositing will always be closest to where the depositions occur, which leads to a higher deposition rate per time unit and improved utilization of the gas. The residual gas located towards the center of the reactor escapes from the reactor for example through a hole in the center of a top plate.

The centripetal acceleration will also affect the small silicon dust particles, so-called fines, which may form in a CVD reactor. These particles are heavy compared to the gas molecules surrounding them. Hence, these particles will be forced outwardly towards the reactor wall, whereupon they become a part of the deposition on the wall and may be recrystallized. The serious problem that existing CVD reactors have with fines will accordingly be severely reduced.

Thus, the reactor of the invention can additionally be used as a post-processing system for another type of silicon CVD reactor. The reactor is connected to the outlet of a traditional CVD reactor, such as a Siemens reactor. The outlet gas, consisting of silicon-containing gas, small silicon dust particles (fines), residual gas from reaction and possible mixed gas, is set into rotation and is separated. The unused silicon-containing gas and fines are forced outwardly towards the reactor wall, onto which new depositions occur. The light gas exits through the outlet. Thus, the reactor becomes a cleaning system which separates the different components of the outlet gas of today's CVD reactors, replacing the costly cleaning systems presently employed, and at the same time it contributes substantially to the silicon production. Accordingly, reactors of the invention can be connected to the “exhaust” or outlet of any reactor or to any convenient source, including connecting reactors of the invention in series.

Silicon can at present be produced using metallurgical methods, resulting in silicon of metallurgical quality. This makes it possible to construct reactor walls or tubes of silicon at a reasonable price. By that the main volume or a main part of the weight of silicon from a tight or completed reactor is of higher purity than metallurgical silicon, the whole reactor with its contents of silicon of high purity can be melted down for recrystallization and usage in the electronics industry and/or high efficiency solar cells, wherein the average purity will be sufficient. Possibly, the outer part of metallurgical silicon can be removed in a non-contaminating way, for example by water cutting, machining or melting of said layer in case only the very highest purity is acceptable. Optionally, the reactor can be produced from/made of silicon of the same high purity as it produces, which quality is suitable for the electronics industry. The substantially simplified handling of a tight or completed reactor causes less handling and contaminating of the silicon than what is achievable today.

The devices for heating the reactor in accordance with the invention can be selected among all known, operatively applicable heating devices, however, they advantageously comprise a coherent or non-coherent heating light source of any suitable wavelength and effect, such as for example a micro-wave source, a radio wave source, a source to visible light, a source to infrared light and/or a source to ultra-violet light, preferably a source to infrared light.

### FIGURES

Some embodiments of the inventions are illustrated in the drawings, wherein

FIG. 1 illustrates a vertical reactor according to the invention, with a circular or in substance circular cross-section,

FIG. 2 illustrates a vertical reactor with a helical heating device on the outside,

FIG. 3 illustrates an implementation of inlets in a bottom of a vertical reactor, and

FIG. 4 illustrates a particularly advantageous reactor according to the invention.

### DETAILED DESCRIPTION

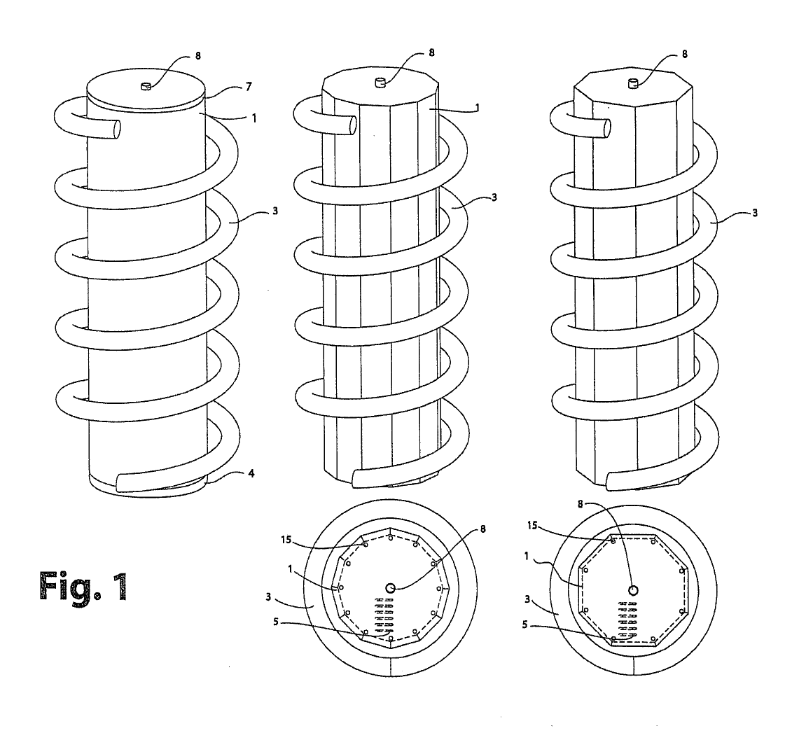

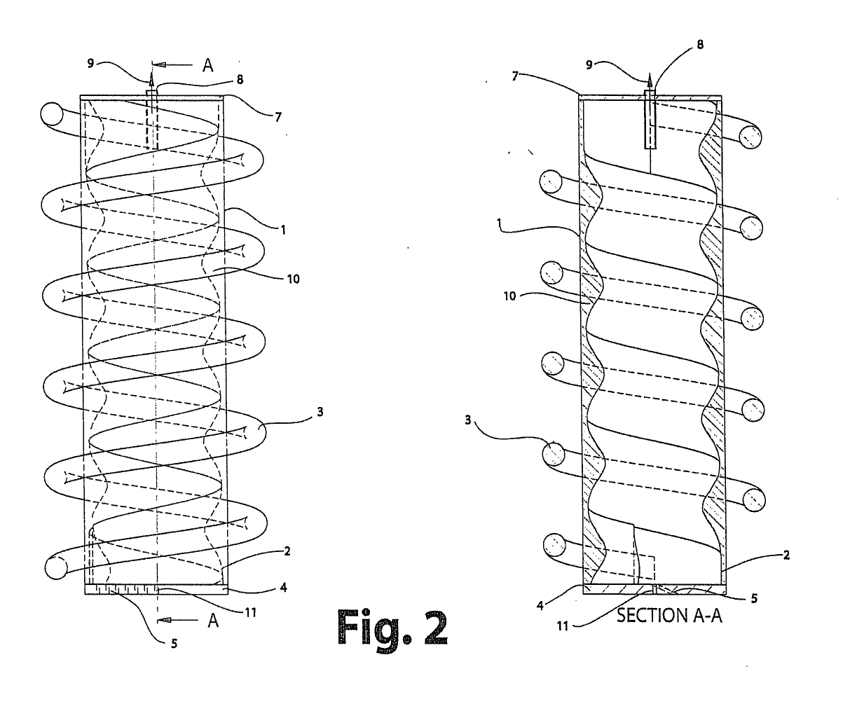

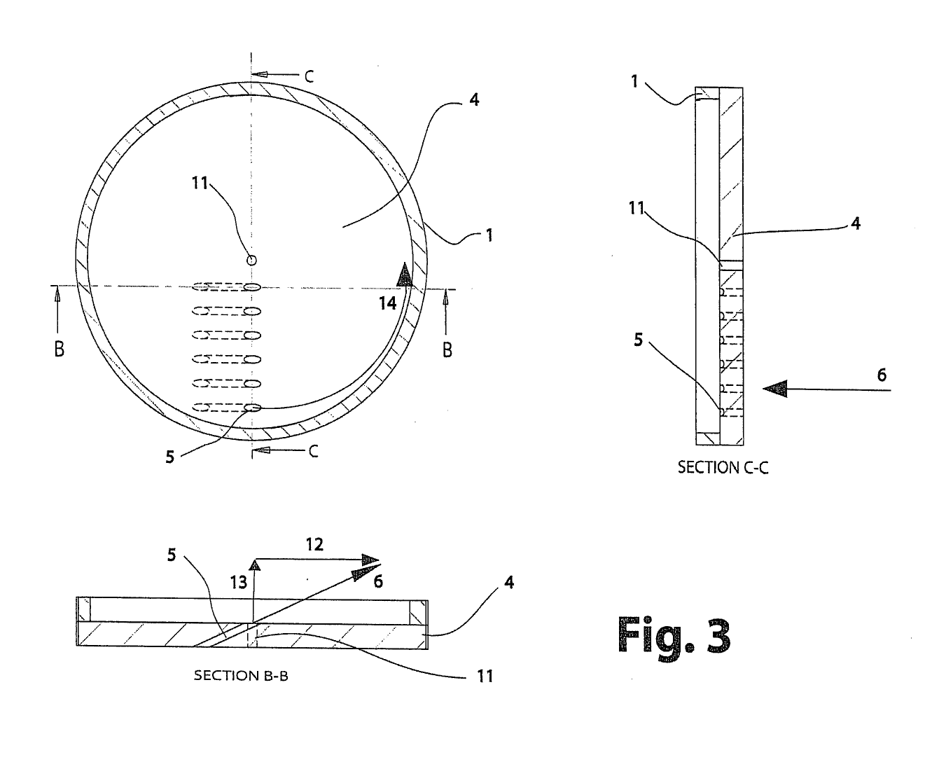

Referring to FIG. 1, the reactor is a closed or in substance closed cylindrical or polygonal vessel with wall (1), top plate (7) and bottom plate (4), preferably produced from/made of silicon of metallurgical purity or purer. Alternatively, the reactor is made of other feasible materials. A polygonal vessel will be assembled from plain plates. The reactor is surrounded by heating elements (3) formed as a spiral or a helix around the reactor, either complete or divided into sections. Said heating elements can also be implemented as short, straight elements, sloping so that they add up to an approximate spiral. The reaction gas (6) which is fed in through the bottom plate (4) is a silicon-containing gas, preferably SiH₄ or SiHCl₃, in most cases mixed with H₂ gas. Referring to FIGS. 2 and 3, the bottom plate (4) of the reactor comprises one or more through-going holes (5) which function as nozzles for the reaction gas (6). The holes can ideally be positioned on a line between the center of the cylinder and the cylinder wall, in such a way that new nozzles can be put to use as the wall grows inwardly. Possibly, several nozzles can be arranged around the circumference. The nozzle holes (5) are designed in such a way that the gas flow acquires a tangential (12) as well as a vertical velocity component. This is achieved in that the sloping holes extend through the bottom plate, seen from one side, as illustrated by FIG. 3. The angle of the holes is preferably equal to the helix angle, the slope angle, of the heating elements. Thereby, the gas flow will obtain a rotation (14) about the center line of the reactor and follow the inside of the cylinder wall (2) as it moves vertically upward. The top plate (7) also comprises holes (8) through which the residual gas (9) can escape, which gas is residue of the reaction gas (6), consisting mainly of H₂, in a nearly ideal process. The hole (8) in the top plate (7) is positioned in the center, in such a way that the silicon-poor residual gas (9) can escape, whereas the remaining reaction gas (6) can rotate along the reactor wall (2) until as much as possible of the silicon has been liberated. It may be advantageous if the hole (8) is tubular shaped and extends somewhat downwardly into the reactor. This could cause a cyclone effect, which could further increase the utilization of the reaction gas. A gas flow with reaction gas (6) is fed through the holes (5) in the bottom plate (4) at ideal velocity, preferably with parallel streamlines, that is, in such a way that a helical flow extends all the way to the top of the reactor. The reaction gas (6) enters the bottom of the reactor, tangential to the inside of the wall (2) at an upwardly inclined angle. Thus, the gas will follow the wall (2) and rotate about the center line of the reactor. Silicon is deposited onto the heated wall (2) and the depositions form a helix (10) on the inside of the reactor wall (2) due to the position of the heating elements (3) and the varying heating of the reactor wall. The residual gas (9) will finally escape through the hole (8) in the top plate (7).

The bottom plate (4) can be equipped with a concentric hole (11) in order to allow vertical injection of additional reaction gas (6). This could contribute to an even more balanced deposition of silicon in the vertical direction of the reactor, particularly if the flow velocity of the helical flow is considerably larger than the flow velocity of the vertical injection flow. The centric gas beam of reaction gas will be caught by the rotation reaction gas (14) and forced outwardly towards the inside of the reactor wall (2). It is advantageous if the vertical deposition can be controlled through the cross-section of the centric hole (11) and the gas beam up through the centric hole (11). In a polygonal vessel the bottom plate can be additionally equipped with vertical holes (15), positioned in each corner in the transition between two sidewalls. By feeding a vertical gas flow with reaction gas through the holes (15) for some time when initiating the reactor, silicon can quickly deposit between the sidewalls, hence sealing the reactor. Thereby a very early limitation of the leakage of silicon-containing gas is achieved, as the leakage causes a gradual sealing of the joints, causing a polygonal vessel to obtain a more circular inner cross-section, which is advantageous for the rotation. Leaked silicon-containing gas can however deposit onto the reactor wall, particularly onto a heat light heated reactor wall.

A gas flow with reaction gas (6) will be exposed to the heated reactor wall (2) and silicon is deposited by CVD. Most silicon will deposit onto where the wall is hottest, that is, in the area closest to the heating elements. Thus the depositions will form a helix (10) on the inside of the cylinder wall, equal to the helical heating devices. This helix (10) will aid the gas flow in maintaining the rotation inside the reactor. As the helical shaped depositions increase in thickness, the temperature differences in the silicon wall (2) will even out, and deposition will therefore occur more evenly onto the whole reactor wall (1). The whole reactor is removed and replaced with a new silicon reactor when the tube has grown tight and is filled with pure silicon all the way to the center of the reactor, or as far as it is economically justifiable to run the process. The increasing wall thickness will leave less and less volume for the silicon-containing gas (6), and production per hour will decrease over time and stop completely when the tube is clogged. The heating elements (3) are preferably heat light sources positioned outside the reactor, transmitting the heat through radiation or contact heat to the outer surfaces of the reactor. The heat light source is, as aforementioned, shaped as a spiral around the reactor or as a number of sloping heating elements which together form a spiral or a helix around the reactor. Additionally, the heating devices can be divided into sections on top of each other in order to be able to control the temperature individually in the height of the reactor. The heat is lead from the heat light source (3) through the silicon wall (1) to the inside of the wall (2) which will constitute the hottest surface inside the reactor, onto which surface the depositions advantageously occur.

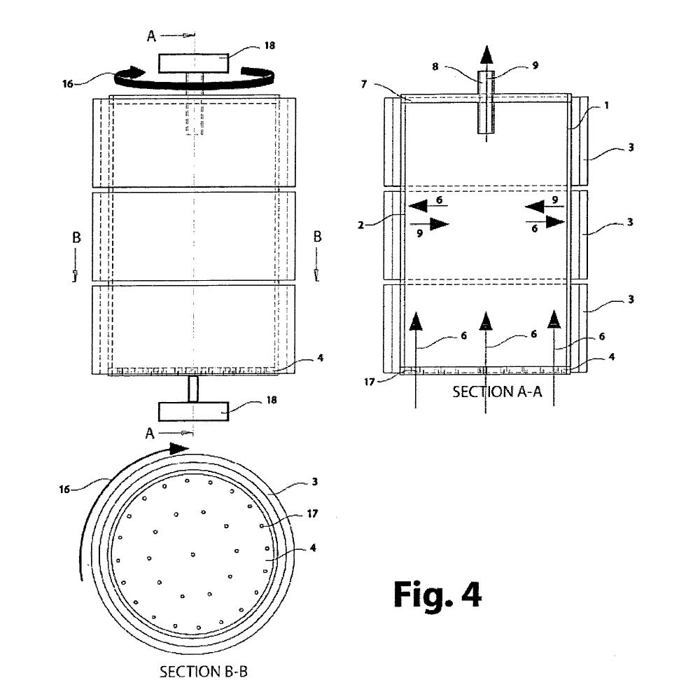

Referring to FIG. 4, the reactor is a closed or nearly closed cylindrical or polygonal (three or more sides) vessel with wall (1), top plate (7) and bottom plate (4). A polygonal vessel will be assembled from plane plates. The vessel is preferably made of a non-contaminating material, preferably silicon of sufficient purity so that in substance the whole reactor can be utilized further in the production. The reactor is thus meant to be used only once, in a batch process. The reactor is surrounded by heating devices (3), either complete or divided into sections. The heating elements can possibly be stationary, rod shaped elements. The reaction gas (6) which is fed in through the bottom plate (4) is a silicon-containing gas, preferably SiH4 or gas with silicon fines, in most cases mixed with H₂ gas. The bottom plate (4) of the reactor comprises one or more through-going straight holes (17) which function as nozzles for the reaction gas (6). The holes (17) can be positioned in an infinite number of ways and can be shaped in many different ways, depending on the desirable flow pattern. Holes (17) between the center of the cylinder and the cylinder wall might be sensible, so that new nozzles can be put to use as the wall is growing inwards. The top plate (7) also comprises holes (8) in order to let the residual gas (9) escape, which is residue from the reaction gas (6) and consists mainly of H₂, in a nearly ideal process. The hole (8) in the top plate (7) is positioned in the center, in such a way that the silicon-poor residual gas (9) can escape, whereas the remaining reaction gas (6) can stay in the reactor until as much as possible of the silicon has been liberated. It might also be advantageous if the hole (8) is tubularly shaped and extends somewhat downwardly into the reactor. This could cause a cyclone effect, which could further increase the utilization of the reaction gas.

A gas flow with reaction gas (6) is fed through the holes (17) in the bottom plate (4) at optimal velocity, advantageously resulting in parallel streamlines or flow pattern. The reaction gas (6) enters through the bottom plate (4) and moves upwardly through the reactor. By putting the whole reactor into rotation (16), the reaction gas (6) will be exposed to centripetal acceleration which forces the gas (6) towards the wall of the reactor. The silicon-containing gas is substantially heavier than the residual gas (9) and will thus be exposed to the larger force. This results in the silicon-containing gas (6) being forced closest to the heated wall (2) onto which the silicon is deposited, whereas the residual gas (9) has to yield and move closer to the center of the reactor. The residual gas (9) will finally escape through the hole (8) in the top plate (7). The reactor can possibly be vertical, sloping or with inlets at the top and outlets at the bottom. The reaction gas (6) is exposed to centripetal forces in that the whole or parts of the reactor is rotating (16) at a sufficient rotation velocity. This can be achieved in that a motor (not shown in figure) puts the reactor into rotation (16). It is generally only necessary to rotate the reactor walls (1), however, it is advantageous if the bottom and top plate (4 and 7) also rotate (16) in order to achieve the best possible flow pattern. If it, due to construction considerations, is more expedient to let heating elements (3), measuring devices (not shown in figure), insulation (not shown in figure) and other elements surrounding the reactor, rotate with the reactor, this is possible. Gas going in (6) and out (9) needs to travel through special couplings (18) allowing rotation, such as a swivel coupling. Most of the electronics and measuring devices (not shown in figure) can advantageously be wireless.

The reaction gas (6) will reach the same rotation as the reactor, and will thus have no tangential velocity component relative to the reactor wall (2), only a small velocity component upwardly along the reactor wall (2). This results in a small relative velocity between the reaction gas (6) and the wall (2) onto which it should deposit, which is advantageous in order to avoid the formation of particles or fines. The centripetal forces arising due to the rotation (16) will force the reaction gas (6) outwardly towards the reactor wall (1). The gas will be separated in that the heaviest molecules are exposed to the largest forces, thus, they will be positioned closest to the wall. The light molecules will have to yield to the heavier ones, thus being positioned closer to the rotation axis. In this particular case, this is especially advantageous in that the silicon-containing reaction gas (6) is substantially heavier than the residual gas (9) from which most of the silicon has been liberated. Thus, a gradient with heavy reaction gas (6) closest to the wall and light residual gas (9) inwardly towards the center of the reactor will form. This results in a higher deposition rate due to the fact that the reaction surface (2) quickly will be provided with new reaction gas. This will most likely also increase the gas utilization, decreasing the silicon concentration in the exhaust gas.

In a polygonal vessel, the bottom plate can additionally be equipped with vertical holes (15) positioned in each corner in the transition between two sidewalls. By feeding a vertical gas flow with reaction gas through the holes (15) for some time when initiating the reactor, silicon will quickly deposit between the sidewalls, thus nearly sealing the reactor. This can be done before the reactor starts rotating. Thereby an early limitation of the leakage of silicon-containing gas is achieved, as the leakage causes a gradual sealing of the joints and a polygonal vessel obtains a more circular inner cross-section. A gas flow with reaction gas (6) will be exposed to the hot reactor wall (2) and silicon will deposit by chemical vapor deposition (CVD). More silicon will deposit where the wall is hottest, thus, the deposition can be controlled in such a way that the depositions will be evenly distributed throughout the whole reactor. The whole reactor is removed and replaced with a new reactor when the reactor has grown tight and is filled with pure silicon all the way to the center of the reactor, or as far as it is economically justifiable to run the process. The increasing wall thickness will lead to less and less volume for the silicon-containing gas (6) and the production per hour will decrease over time and stop completely when the tube is clogged.

When the reactor is so full that it is no longer expedient to keep running the process, gas injection, rotation and heat supply are stopped. The reactor is removed from the vessel with the heating elements (3) and a new, empty reactor is inserted, in such a way that the CVD process can be started anew. Hence, it is not a continuous process but a batch process, however, the change can occur so rapidly that the highest possible production is achieved. The reactor filled with silicon can be brought directly to further processing, for example into a melting furnace. When using another material than silicon in the reactor walls (1), bottom plate (4) and/or top plate (7), this material needs to be removed, for example by machining, before the reactor can be used in further processing. The outer dimensions of the reactor can be adapted to the further processing.

The heating elements (3) are preferably heat light sources positioned outside the reactor, transmitting the heat through radiation or contact heat to the outer surfaces of the reactor. The heating devices may be divided into several sections on top of each other in order to be able to control the temperature individually in the height of the reactor. The heat is conducted from the heat light source (3) through the silicon wall (1) to the inside of the wall (2), which constitutes the hottest surface inside the reactor, onto which surface the deposition advantageously occurs. Heat light sources can also be arranged on the bottom or top plate, protected in that the heat light sources are coaxially arranged in an inert/cooling gas inlet, which is particularly advantageous and energy efficient in that heating occurs directly on the surface onto which deposition of silicon takes place. The reactor and method of the invention comprises features and/or steps as described, mention or illustrated in this document, in any operative combination, which combinations are embodiments of the reactor and method of the invention, respectively.

1. A reactor for production of silicon, comprising:
a reactor volume; and
wherein the reactor comprises or is operatively arranged to at least one means for setting a silicon-containing reaction gas for chemical vapor deposition (CVD) into rotation inside the reactor volume.

2. The reactor according to claim 1, wherein the reactor volume is made of silicon or has an inner silicon layer so that a silicon surface forms the inner surface against at least a part of the reactor volume.

3. The reactor according to claim 1, wherein the reactor comprises a shape as a cylinder with a circular or in substance circular cross-section, the cylinder is vertically orientated the sidewalls are made of silicon of metallurgical quality or purer, and one or more inlets are angularly arranged in a bottom, so that silicon-containing gas is guided in a helical path upwardly along the wall towards an outlet in the top of the reactor, wherein the orientation of the inlet and the gas contains a direction component parallel to the cylinder axis and a direction component parallel to the circumference of the inner cylindrical wall.

4. The reactor according to claim 1, wherein the reactor comprises or is operatively arranged to a heating device outside the reactor.

5. The reactor according to claim 1, wherein the reactor comprises a shape as a cylinder with a circular inner cross-section, a motor for rotating the reactor operatively connected to the reactor, a outlet for silicon-poor gas arranged coaxially to the cylinder axis in at least one end, at least one inlet for silicon rich reaction gas, at least one heating device operatively arranged on the outside or on the inside of the reactor, with or without inert gas and/or cooling gas protection.

6. The reactor according to claim 1, wherein motor is operatively connected to the reactor for rotating said reactor, the reactor comprising at least one end plate rotating with the reactor, which end plate is equipped with at least one but preferably several inlets for silicon-containing reaction gas and the end plates are preferably made of a material having lower thermal conductivity than the rest of the reactor, such as a composite construction of materials of different thermal conductivity in order to avoid deposition in the inlets as well as minimizing thermal losses.

7. A method for production of silicon by vapor deposition and/or cleaning of a silicon containing gas in a reactor, the method comprising:
setting a silicon-containing reaction gas for chemical vapor deposition (CVD) into rotation inside a reactor volume, by operating at least one means for achieving such rotation.

8. The method according to claim 7, wherein the silicon deliberately is deposited onto the reactor wall by chemical vapor deposition in such a way that the cross-section of the reactor principally grows tight, whereupon the contents of said reactor or the contents of said reactor as well as the reactor wall is utilized in further stages in a process for production of silicon for solar cell and/or electronic purposes.

9. Use of a reactor according to claim 1, for producing silicon and/or cleaning silicon containing reaction gas supplied from other reactors or other types of CVD reactors, or the gas is originating from other sources.

10. The reactor according to claim 1, wherein the wall of the reactor is made of any material withstanding the operating conditions, preferably a low-contaminating material such as quartz, silicon-nitride or graphite.
